(19) United States
(12) Patent Application Publication
(10) Pub. No.: US 2026/0239547 A1
(43) Pub. Date: Aug. 13, 2026

(54) MOUNTING AND SUPPORT DEVICES AND SYSTEMS

(71) Applicant: Miro Industries, Inc., Heber City, UT (US)

(72) Inventors: Jason Reed Haddock, Heber City, UT (US); Jarrett Welch, Heber City, UT (US); Samuel Richard Robins, Heber City, UT (US); Chance Spensko, Heber City, UT (US); Kolten Post, Heber City, UT (US)

(21) Appl. No.: 19/534,526

(22) Filed: Feb. 9, 2026

Related U.S. Application Data
(60) Provisional application No. 63/755,923, filed on Feb. 7, 2025.

(51) Int. Cl. H05K 5/02

(52) U.S. Cl. CPC H05K 5/0217

(57) ABSTRACT

The present disclosure relates to the mounting and support of a variety of different objects or items. In one form, a mounting device includes a mounting platform, and first and second support members spaced from one another and extending from the mounting platform. First and second base members extend toward one another from a respective one of the first support member and the second support member, and a number of brace members provide support to the first and second support members. A plurality of apertures are provided on each of the mounting platform, the support members, and the base members to provide a number of different options for coupling other objects or items with the mounting device as desired. A system may include a plurality of mounting devices and a number of support devices configured for coupling with and supporting the mounting devices on a surface underlying the support devices.

### CROSS-REFERENCE TO RELATED APPLICATIONS

This application claims the benefit of United States Patent Application Serial No. 63/755,923, filed on Feb. 7, 2025; the disclosure of which is incorporated herein by reference in its entirety.

### FIELD

The present disclosure generally relates to the mounting and support of a variety of different objects or items. More particularly, but not exclusively, the present disclosure relates to a mounting device to which a variety of other objects or items may be coupled, including for example in the context of a rooftop or similar setting. The mounting device may be coupled with one or more support devices in a system which provides mounting and support functions. The system may include a plurality of the mounting devices.

### BACKGROUND

Unless otherwise indicated herein, the materials described herein are not prior art to the claims in the present application and are not admitted to be prior art by inclusion in this section.

Various objects, including HVAC ductwork, HVAC components such as condenser units, refrigeration lines, electric conduit and/or modular walkways, amongst others, may be positioned on the rooftop of a structure. Membrane materials may be used on rooftops, and these materials may be damaged by positioning objects directly thereon. The rooftops themselves may also present an uneven surface for positioning these objects. In order to provide organization and secure positioning of these items, as well as to address the aforementioned issues, there is a need for additional contributions in this area of technology.

The subject matter claimed herein is not limited to implementations that solve any disadvantages or that operate only in environments such as those described above. Rather, this background is only provided to illustrate one example technology area where some implementations described herein may be practiced.

### SUMMARY

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

In one embodiment, a mounting device includes a mounting platform, a first support member extending from the mounting platform in a first direction, and a second support member spaced from the first support member and extending from the mounting platform in the first direction. The mounting device further includes a first base member extending from the first support member toward the second support member, a second base member extending from the second support member toward the first support member, and a number of brace members configured to provide support to the first support member and the second support member. Each of the mounting platform, the first support member, the second support member, the first base member and the second base member includes a plurality of apertures extending therethrough.

In another embodiment, a system includes a first mounting device as described herein, and a first support device and a second support device each configured for coupling with and supporting the first mounting device on an underlying surface. The system may further include a second mounting device as described herein, and a third support device and a fourth support device each configured for coupling with and supporting the second mounting device on an underlying surface.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a perspective view of a mounting and support system;

FIG. 2 is a side view of a portion of the system illustrated in FIG. 1;

FIG. 3 is a perspective view of the system illustrated in FIG. 1 with a condensing unit positioned thereon; and

FIG. 4 is a perspective view of an alternative embodiment mounting and support system with a condensing unit positioned thereon.

### DETAILED DESCRIPTION

Reference will now be made to the drawings to describe various aspects of example embodiments of the invention. It is to be understood that the drawings are diagrammatic and schematic representations of such example embodiments, and are not limiting of the present invention, nor are they necessarily drawn to scale.

The present disclosure generally relates to the mounting and support of a variety of different objects or items. More particularly, but not exclusively, the present disclosure relates to a mounting device to which a variety of other objects or items may be coupled, including for example in the context of a rooftop or similar setting. The mounting device may be coupled with one or more support devices in a system which provides mounting and support functions. The system may include a plurality of the mounting devices. It will be appreciated that embodiments disclosed herein may be employed in a variety of fields and/or operating environments where the functionality disclosed herein may be useful. Accordingly, the scope of the invention should not be construed to be limited to the exemplary implementations and operating environments disclosed herein.

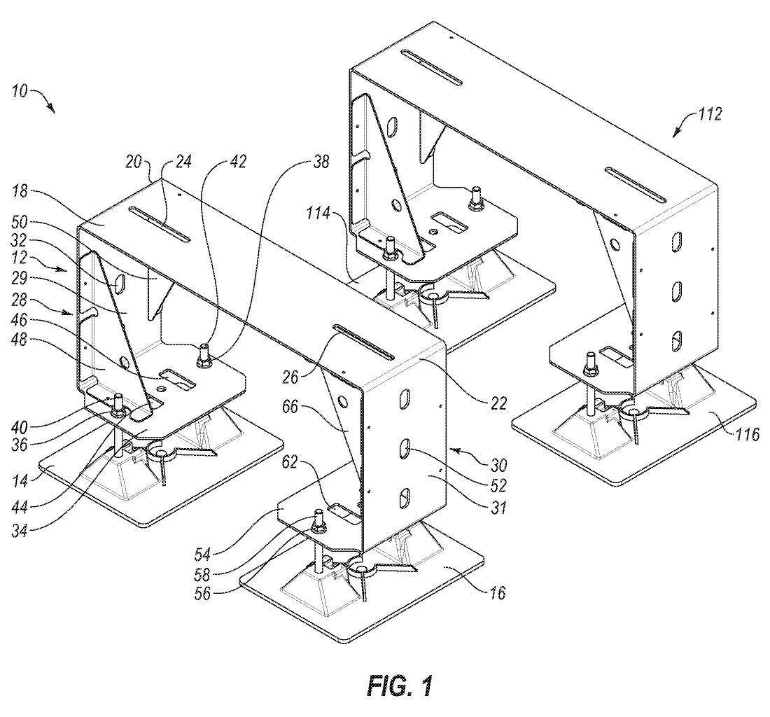

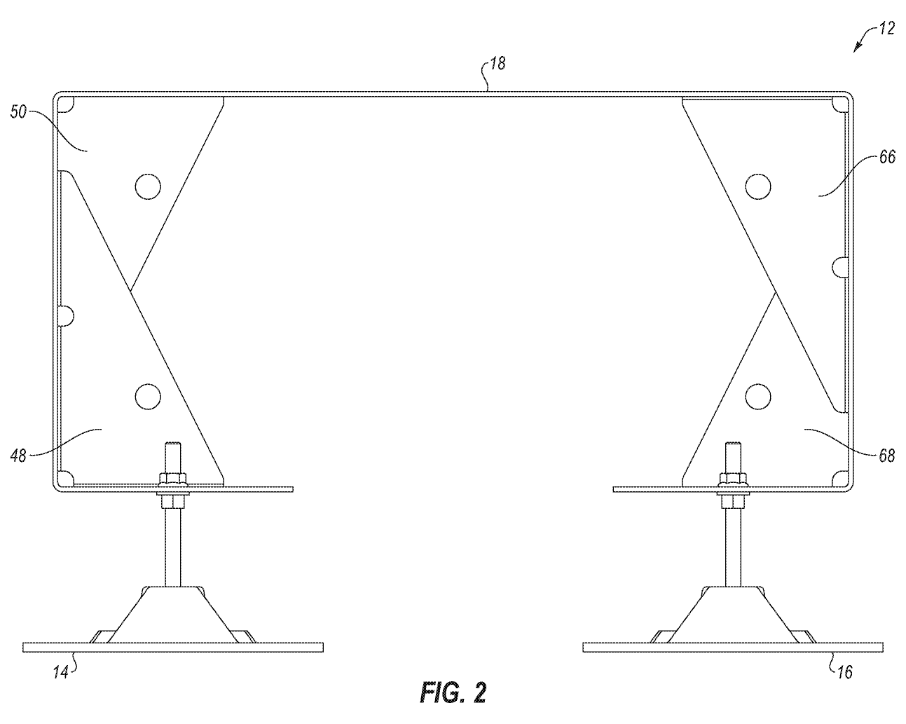

With general reference to FIGS. 1-3 for example, there is illustrated one embodiment of a mounting and support system 10. The system 10 includes a mounting device 12, and a first support device 14 and a second support device 16 which are coupled with the mounting device 12. The mounting device 12 includes a mounting platform 18 which extends between a first end 20 and an opposite second end 22. The mounting platform 18 includes a first elongated slot 24 and a second elongated slot 26, which in the illustrated form are spaced from one another and positioned between the first end 20 and the second end 22. However, variations in the size, shape and positioning of the first elongated slot 24 and the second elongated slot 26 are possible and contemplated.

A first support member 28 includes a body 29 extending from the mounting platform 18 in a first direction and a second support member 30 includes a body 31 which also extends from the mounting platform 18 in the first direction. In the illustrated form, the body 29 of the first support member 28 generally extends from the first end 20 of the mounting platform 18 and the body 31 of the second support member 30 generally extends from the second end 22 of the mounting platform 18. However, it should be appreciated that variations in the positioning of the first support member 28 and the second support member 30 relative to the mounting platform 18 are possible. For example, in one non-illustrated form, one or both of the first support member 28 and the second support member 30 may extend from the mounting platform 18 at locations which are positioned between the first end 20 and the second end 22 of the mounting platform 18.

The first support member 28 includes a plurality of apertures 32 extending therethrough, only some of which have been identified in the Figures in order to preserve clarity. In the illustrated form, the apertures 32 have an elongated configuration, although variations in the configuration are possible. The first support member 28 includes a base member 34 extending from the body 29 toward the second support member 30. The base member 34 includes a pair of apertures 36 and 38 which may include a circular configuration and through which coupling members 40 and 42 extend in the illustrated form. Further details of the coupling members 40 and 42 will be provided below. The base member 34 further includes a pair of elongated slots 44 and 46 positioned between the apertures 36 and 38.

The first support member 28 also includes a first brace member 48 and a second brace member 50. In the illustrated form, the first brace member 48 and the second brace member 50 each generally have a triangular configuration, although other variations are possible. The first brace member 48 is coupled with and extends between the body 29 of the first support member 28 and the base member 34 of the first support member 28. The second brace member 50 is coupled with and extends between the body 29 of the first support member 28 and the mounting platform 18. The first and second brace members 48 and 50 are configured to provide support and rigidity between the mounting platform 18 and the first support member 28.

The second support member 30 includes a plurality of apertures 52 extending therethrough, only some of which have been identified in the Figures in order to preserve clarity. In the illustrated form, the apertures 52 have an elongated configuration, although variations in the configuration are possible. The second support member 30 includes a base member 54 extending from the body 31 toward the first support member 28. The base member 54 may be the same as or substantially similar to the base member 34. Similarly, the base member 54 includes a pair of apertures which may include a circular configuration. For the sake of clarity, in the Figures only aperture 56 of the base member 54 is identified. A pair of coupling members 58 and 60 extend through the apertures of the base member 54, and further details of the coupling members 58 and 60 will be provided below. The base member 54 further includes a pair of elongated slots positioned between the apertures thereof. For the sake of clarity, in the Figures only elongated slot 62 of the base member 54 is identified.

The second support member 30 also includes a third brace member 66 and a fourth brace member 68. In the illustrated form, the third brace member 66 and the fourth brace member 68 each generally have a triangular configuration, although other variations are possible. The third brace member 66 is coupled with and extends between the body 31 of the second support member 30 and the mounting platform 18. The fourth brace member 68 is coupled with and extends between the body 31 of the second support member 30 and the base member 54 of the second support member 30. The third and fourth brace members 66 and 68 are configured to provide support and rigidity between the mounting platform 18 and the second support member 30.

While not previously discussed, it should be appreciated that the base members 34 and 54 each include a width which is greater than the width of a respective one of the body 29 of the first support member 28 and the body 31 of the second support member 30. In this configuration, the base members 34 and 54 may be configured to provide stability to the mounting device 12 in order to avoid, or promote avoidance of, the mounting device 12 tipping over when a force is applied thereto from a direction transverse to the long axis of the mounting device 12. Further, in the illustrated form there is space separating and extending between the base member 34 and the base member 54, and this space is less than the length of the mounting platform 18 between the first and second ends 20, 22 thereof.

Turning now to the first support device 14 and the second support device 16, these devices may be configured to be coupled with the mounting device 12 and to distribute the weight of the mounting device 12 (and any components coupled to or positioned thereon) over a surface underlying the first support device 14 and the second support device 16 in a manner which avoids, or at least partially avoids, damaging the surface. The first support device 14 is further configured to engage with the coupling members 40 and 42 and the second support device 16 is further configured to engage with the coupling members 58 and 60 in order to provide coupling between the first and second support devices 14, 16 and the mounting device 12. In the illustrated form, the coupling members 40, 42, 58 and 60 are externally threaded members, although other variations are possible. By way of example, the first and second support devices 14, 16 may include internally threaded receptables configured to engage with the coupling members 40, 42, 58 and 60. Alternatively, the first and second support devices 14, 16 may be provided with a flange or similar structure through which the coupling members 40, 42, 58 and 60 may be positioned and an internally threaded member, such as a nut, may be positioned on either side of the flange or similar structure in order to engage the coupling members 40, 42, 58 and 60 with the first and second support devices 14 and 16. However, other variations are possible.

Each of the coupling members 40, 42, 58 and 60 may extend through a respective one of the base members 34 and 54, and an internally threaded member, such as a nut, may be positioned on either side of the base members 34 and 54 in order to engage the coupling members 40, 42, 58 and 60 with the base members 34 and 54. The engagement of the coupling members 40, 42, 58 and 60 with at least one of the first and second support devices 14, 16 and the base members 34, 54 may be adjusted in order to change the relative positioning between the first and second support devices 14, 16 and the mounting device 12. In this arrangement, variations in the surface underlying the support devices 14, 16, such as flatness or levelness, may be accounted for by adjusting the coupling members 40, 42, 58 and 60 as necessary in order to provide the mounting platform 18 with a desired configuration. For example, the coupling members 40, 42, 58 and 60 may be adjusted to provide the mounting platform 18 with a level orientation despite that a surface thereunder may be unlevel.

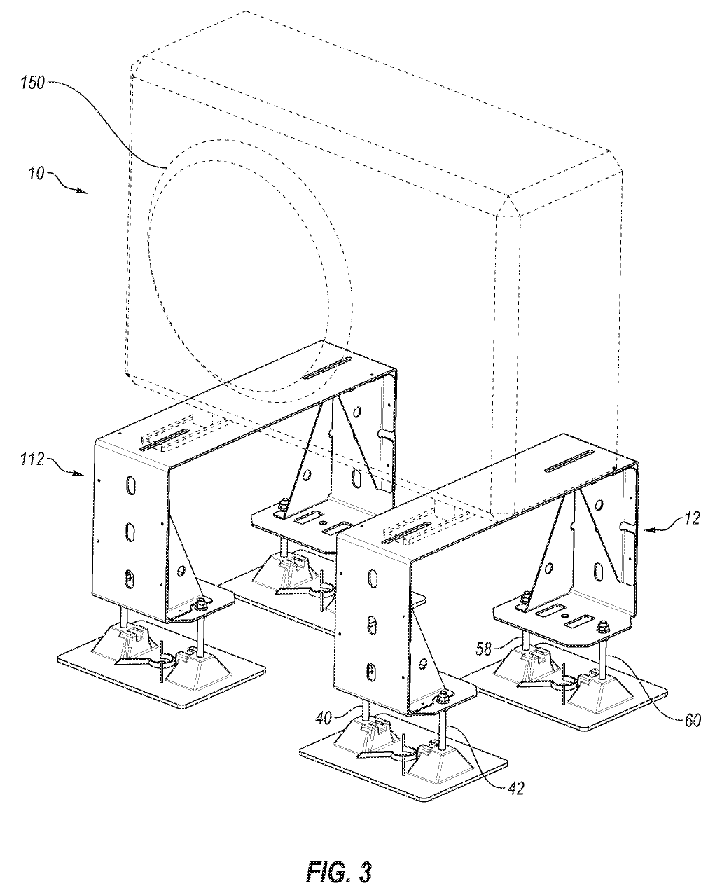

In addition to the elements of the system 10 previously described, the system 10 also includes a second mounting device 112, and a third support device 114 and a fourth support device 116 which are coupled with the second mounting device 112, although forms in which these latter items are omitted from the system 10 are contemplated. The second mounting device 112, the third support device 114 and the fourth support device 116, along with the coupling and adjustability between these components, may be the same or substantially similar to the mounting device 12, the first support device 14 and the second support device 16 and the coupling and adjustability between these components as described above, although variations between these components are possible. In this arrangement, the second mounting device 112, the third support device 114 and the fourth support device 116 may be positioned relative to the mounting device 12, the first support device 14 and the second support device 16 in a manner which allows the mounting or positioning of an item or object spanning between the first and second mounting devices 12 and 112. An arrangement of this nature is illustrated in FIG. 3 for example, where a condensing unit 150, such as a mini-split condensing unit, is mounted on and extends between the first and second mounting devices 12 and 112. By way of example, one or more fasteners may extend through the elongated slots 24 and 26 which may provide for flexibility in the positioning of the condensing unit 150 relative to the first and second mounting devices 12 and 112. It should be understood that the relative positioning of the first mounting device 12 relative to the first and second support devices 14 and 16, and/or the relative positioning of the second mounting device 112 relative to the third and fourth support devices 114, 116, may be adjusted in order to provide a desired orientation/positioning of the condensing unit.

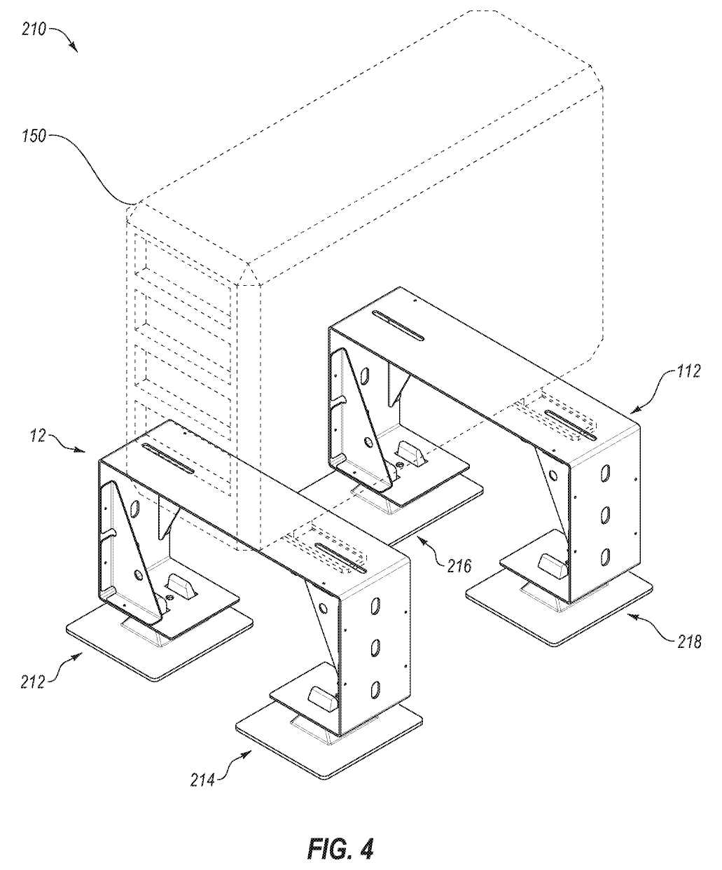

Referring now to FIG. 4, there is illustrated an alternative embodiment system 210, where like numerals refer to like features previously described. The system 210 is substantially similar to the system 10, provided that in the system 210 the support devices 212 and 214 each include a number of tabs which may be positioned in the elongate slots of the base members of the mounting device 12 in order to couple the mounting device 12 with the support devices 212 and 214, and the support devices 216 and 218 each include a number of tabs which may be positioned in the elongate slots of the base members of the mounting device 112 in order to couple the mounting device 112 with the support devices 216 and 218. In this arrangement, it should be appreciated that the relative positioning between the mounting devices 12 and 112 and the support devices 212, 214, 216 and 218 may generally be fixed.

It is contemplated that the systems 10, 210 may also include a number of mounting devices and/or support devices in addition to those illustrated. Similarly, a system may include an arrangement where these components are linked or coupled together and which provides the ability to mount or position a plurality of condensing units. By way of example, these components may be directly coupled together, or one or more additional components may be used to couple these components to one another. Moreover, it should be understood that the components of the system 10 may be used to support objects in addition to or in lieu of the condensing unit. For example, one or more items could be positioned on or coupled to the support members of the mounting devices.

The devices and systems described herein may be used in connection with providing support and/or securing positioning of a number of different objects. A few non-limiting examples of different objects which may be supported by the devices described herein include HVAC ductwork, HVAC components such as condensing units, including mini-split condensing units, refrigeration lines, electric conduit, plumbing lines and/or modular walkways. In addition, the devices described herein may be made from a variety of different materials. In some aspects, the support devices may be made from a polymer or plastic material and the mounting devices may be made from a metallic or similar material. However, other variations are possible and contemplated.

In one embodiment, a mounting device includes a mounting platform, a first support member extending from the mounting platform in a first direction, and a second support member spaced from the first support member and extending from the mounting platform in the first direction. The device also includes a first base member extending from the first support member toward the second support member, a second base member extending from the second support member toward the first support member, and a number of brace members configured to provide support to first support member and the second support member. Each of the mounting platform, the first support member, the second support member, the first base member and the second base member includes a plurality of apertures extending therethrough.

In one form, each of the first base member and the second base member includes a pair of elongated slots positioned between a pair of circular apertures.

In another form, the mounting platform includes a pair of elongate slots positioned between the first support member and the second support member.

In yet another form, the first support member includes a plurality of elongated slots positioned between the mounting platform and the first base member and the second support member includes a plurality of elongated slots positioned between the mounting platform and the second base member.

In still another form, one or more of the number of brace members extends between at least one of the mounting platform and the first support member, the mounting platform and the second support member, the first support member and the first base member, and the second support member and the second base member.

In another form, a first one of the number of brace members extends between the mounting platform and the first support member and a second one of the number of brace members extends between the first support member and the first base member.

In one aspect, a third one of the number of brace members extends between the mounting platform and the second support member and a fourth one of the number of brace members extends between the second support member and the second base member.

In yet another form, a distance separating the first base member and the second base member is less than a length of the mounting platform between the first support member and the second support member.

In another embodiment, a system includes at least one mounting device as described herein, and a first support device and a second support device each configured for coupling with and supporting on an underlying surface the mounting device.

In one form, the first support device and the second support device are configured to engage with the first mounting device.

In one aspect, each of the first support device and the second support device includes a pair of tabs configured to engage with corresponding slots on a respective one of the first base member and the second base member of the mounting device.

In another form, the system further includes a number of adjustable coupling members each configured to engage with the mounting device and a respective one of the first support device and the second support device.

In one aspect, each of the adjustable coupling members is configured to provide adjustability in relative positioning between the mounting device according and the first support device and the second support device.

In another form, the system further includes a second mounting device as described herein, a third support device, and a fourth support device, where each of the third support device and the fourth support device is configured for coupling with and supporting on an underlying surface the second mounting device.

Unless specific arrangements described herein are mutually exclusive with one another, the various implementations described herein can be combined to enhance system functionality or to produce complementary functions. Likewise, aspects of the implementations may be implemented in standalone arrangements. Thus, the above description has been given by way of example only and modification in detail may be made within the scope of the present invention.

With respect to the use of substantially any plural or singular terms herein, those having skill in the art can translate from the plural to the singular or from the singular to the plural as is appropriate to the context or application. The various singular/plural permutations may be expressly set forth herein for sake of clarity. A reference to an element in the singular is not intended to mean “one and only one” unless specifically stated, but rather “one or more.” Moreover, nothing disclosed herein is intended to be dedicated to the public regardless of whether such disclosure is explicitly recited in the above description.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). Furthermore, in those instances where a convention analogous to “at least one of A, B, and C, etc.” is used, in general, such a construction is intended in the sense one having skill in the art would understand the convention (e.g., “a system having at least one of A, B, and C” would include but not be limited to systems that include A alone, B alone, C alone, A and B together, A and C together, B and C together, or A, B, and C together, etc.). Also, a phrase presenting two or more alternative terms, whether in the description, claims, or drawings, should be understood to include one of the terms, either of the terms, or both terms. For example, the phrase “A or B” will be understood to include the possibilities of “A” or “B” or “A and B.”

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A mounting device, comprising:
a mounting platform;
a first support member extending from the mounting platform in a first direction;
a second support member spaced from the first support member and extending from the mounting platform in the first direction;
a first base member extending from the first support member toward the second support member;
a second base member extending from the second support member toward the first support member; and
a number of brace members configured to provide support to the first support member and the second support member;
wherein each of the mounting platform, the first support member, the second support member, the first base member and the second base member includes a plurality of apertures extending therethrough.

2. The mounting device of claim 1, wherein each of the first base member and the second base member includes a pair of elongated slots positioned between a pair of circular apertures.

3. The mounting device of claim 1, wherein the mounting platform includes a pair of elongate slots positioned between the first support member and the second support member.

4. The mounting device of claim 1, wherein the first support member includes a plurality of elongated slots positioned between the mounting platform and the first base member and the second support member includes a plurality of elongated slots positioned between the mounting platform and the second base member.

5. The mounting device of claim 1, wherein one or more of the number of brace members extends between at least one of the mounting platform and the first support member, the mounting platform and the second support member, the first support member and the first base member, and the second support member and the second base member.

6. The mounting device of claim 1, wherein a first one of the number of brace members extends between the mounting platform and the first support member and a second one of the number of brace members extends between the first support member and the first base member.

7. The mounting device of claim 6, wherein a third one of the number of brace members extends between the mounting platform and the second support member and a fourth one of the number of brace members extends between the second support member and the second base member.

8. The mounting device of claim 1, wherein a distance separating the first base member and the second base member is less than a length of the mounting platform between the first support member and the second support member.

9. A system, comprising:
a first mounting device according to claim 1;
a first support device and a second support device each configured for coupling with and supporting the first mounting device according to claim 1 on an underlying surface.

10. The system of claim 9, wherein the first support device and the second support device are configured to engage with the first mounting device according to claim 1.

11. The system of claim 10, wherein each of the first support device and the second support device includes a pair of tabs configured to engage with corresponding slots on a respective one of the first base member and the second base member of the first mounting device according to claim 1.

12. The system of claim 9, further comprising a number of adjustable coupling members each configured to engage with the first mounting device according to claim 1 and a respective one of the first support device and the second support device.

13. The system of claim 12, wherein each of the adjustable coupling members is configured to provide adjustability in relative positioning between the first mounting device according to claim 1 and the first support device and the second support device.

14. The system of claim 9, further comprising a second mounting device according to claim 1, a third support device, and a fourth support device, wherein each of the third support device and the fourth support device is configured for coupling with and supporting the second mounting device according to claim 1 on an underlying surface.
